(19) United States
(12) Patent Application Publication
(10) Pub. No.: US 2005/0124086 A1
(43) Pub. Date: Jun. 9, 2005

(54) Method for manufacturing a semiconductor device, and method for manufacturing a wafer

(75) Inventor: Akihiro Fujiwara, Fukuoka (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/975,391

(22) Filed: Oct. 29, 2004

(30) Foreign Application Priority Data
Oct. 30, 2003 (JP) 2003-370084

(51) Int. Cl. H01L 21/00; H01L 27/15; H01L 29/26; H01L 31/12; H01L 33/00

(52) U.S. Cl. 438/29

(57) ABSTRACT

There is provided a semiconductor device manufacturing method including a step of adhering a first conductive-type GaP wafer to a first conductive-type semiconductor layer and capable of manufacturing semiconductor devices having a stable device characteristic with an improved yield. Also, there is provided a method of manufacturing a GaP wafer for use to manufacture the semiconductor device. The wafer is manufactured by forming a GaP buffer layer on the first conductive-type GaP substrate by the MOCVD method without using a first conductive-type impurity material, and doping a first conductive-type impurity into the GaP buffer layer by the ion implantation method or solid phase diffusion method.

### CROSS-REFERENCE TO RELATED APPLICATION

This application is based upon and claims the benefit of priority from prior Japanese Patent Application No. 2003-370084, filed on Oct. 30, 2003, the entire contents of which are incorporated herein by reference.

### BACKGROUND OF THE INVENTION

1. Field of the Invention

The present invention relates to a method for manufacturing a semiconductor device and a method for manufacturing a wafer.

2. Background Art

Being small in size, lightweight, energy efficient, highly reliable, etc., light emitting semiconductor devices such as light emitting diodes, semiconductor lasers and the like have a wide variety of applications, such as light sources for indicators, optical communication devices and the like. Materials for visible-light LEDs currently in use include compound semiconductors such as AlGaAs, GaP, InGaAlP, etc. Of these materials, InGaAlP has a direct-transition-type band structure corresponding to a range of red to green light wavelength. Consequently, InGaAlP has been developed as an LED material which assures a high inner quantum efficiency within the range of red to green light wavelength (cf. Japanese Patent Application Laid Open No. 97-97920).

InGaAlP is formed on a GaAs substrate for lattice matching with the latter. However, the GaAs substrate is impermeable to light from an active layer of InGaAlP. Therefore, if the GaAs substrate is left as it is, a sufficiently high level of light extraction efficiency cannot be attained.

For a higher light extraction efficiency of the InGaAlP semiconductor light emitting device, it has been proposed to form an n-type layer, active layer and p-type layer from an InGaAlP semiconductor sequentially on a GaAs substrate, and then adhere to the p-type layer a p-type GaP substrate permeable to light from the active layer, and finally remove the GaAs substrate which absorbs the light from the active layer. The p-type GaP substrate to be adhered to the p-type layer is widely used in GaP LEDs and the like. Namely, it is a substrate containing a p-type impurity (cf. Japanese Patent Application Laid Open No. 233925/1996). Many of such GaP and GaAs substrates are of 2 inches (about 5 cm) in diameter. The 2-inch diameter substrate is cut into a plurality of chips each having a size of 350×350 μm, for example, and electrodes are formed on each of these chips, and thus many transparent substrate-type semiconductor light emitting devices are manufactured from one substrate.

Since the GaAs substrate which absorbs the light from the InGaAlP active layer is removed, the above transparent substrate-type semiconductor light emitting device has an improved light extraction efficiency and can provide a high optical power. Also, since the p-type impurity density and carrier density in the p-type GaP substrate are set to below a constant value for preventing light absorption of the p-type impurity, the light extraction efficiency can further be improved. In case Zn is used as the p-type impurity in the p-type GaP substrate, for example, the p-type carrier density is controlled to less than about 5×10¹⁸ cm⁻³ for preventing the light absorption.

As above, the transparent substrate-type semiconductor light emitting device, including the InGaAlP active layer and transparent GaP substrate, has been receiving more and more attention for its high optical power. However, there has been a problem that the transparent substrate-type semiconductor light emitting devices cannot be manufactured with a high yield. It should be noted here that different from ordinary semiconductor light emitting devices, the manufacture of the transparent substrate-type semiconductor light emitting device requires a step of adhering the GaP and InGaAlP substrates to each other. So, it has so far been considered that the adhering step causes the low yield.

The above-mentioned transparent substrate-type semiconductor light emitting device is also manufactured by forming a p-type GaP layer on a p-type transparent GaP substrate by the MOCVD method, and adhering the p-type GaP layer to a p-type layer of InGaAlP semiconductor. However, this method also cannot assure a high yield in producing such devices.

The inventor of the present invention conducted repeated experiments to manufacture transparent substrate-type semiconductor light emitting devices with an improved yield. The results of these experiments revealed that the distribution of carrier density was excessively nonuniform in the commercially available GaP substrate. This nonuniform distribution of carrier density in the substrate caused the carrier density distribution at the adhesive interface between the GaP substrate and InGaAlP semiconductor layer to be nonuniform, varying from one position to another on the substrate. It was also found from the experiment results that the semiconductor devices obtained from substrate portions different from each other in carrier density could not be normally operated with application of a specified voltage, and the semiconductor devices could not be manufactured with a satisfactory yield from a portion of the GaP substrate, where the carrier density was low. More specifically, it was found that in the commercially available transparent GaP substrate, the distribution of carrier density was nonuniform in a range of 5×10¹⁷ to 5×10¹⁸ cm⁻³ and a voltage higher than specified had to be applied to a chip product obtained from the portion of the substrate where the carrier density was lower. When applied with a specified voltage, such a chip product failed. The inventor thus understood that control of the nonuniformity in carrier density distribution at the adhesive interface would result in an improved yield in manufacturing of the transparent substrate-type semiconductor light emitting devices.

### SUMMARY OF THE INVENTION

According to a first aspect of the present invention, there is provided a method for manufacturing a semiconductor device comprising:
forming a GaP buffer layer on a first conductive-type GaP substrate serving as a first substrate by an MOCVD method without using a first conductive-type impurity material;
doping a first conductive-type impurity into the GaP buffer layer by an ion implantation method;
forming a light emitting layer on a GaAs substrate serving as a second substrate;
adhering the light emitting layer on the GaAs substrate and the GaP buffer layer on the GaP substrate to each other; and
removing the GaAs substrate, which is opaque to light from the light emitting layer.

Also, according to a second aspect of the present invention, there is provided a method for manufacturing a semiconductor device comprising:
forming a GaP buffer layer on a first conductive-type GaP substrate serving as a first substrate by an MOCVD method without using a first conductive-type impurity material;
doping a first conductive-type impurity into the GaP buffer layer by a solid phase diffusion method;
forming a light emitting layer on a GaAs substrate serving as a second substrate;
adhering the light emitting layer on the GaAs substrate and the GaP buffer layer on the GaP substrate to each other; and
removing the GaAs substrate, which is opaque to light from the light emitting layer.

Also, according to a third aspect of the present invention, there is provided a method for manufacturing a wafer comprising:
forming a GaP buffer layer on a first conductive-type GaP substrate as a first substrate by the MOCVD method without using a first conductive-type impurity material; and
doping a first conductive-type impurity into the GaP buffer layer by the ion implantation method.

Also, according to a fourth aspect of the present invention, there is provided a method for manufacturing a wafer comprising:
forming a GaP buffer layer on a first conductive-type GaP substrate as a first substrate by the MOCVD method without using a first conductive-type impurity material; and
doping a first conductive-type impurity into the GaP buffer layer by the solid phase diffusion method.

Note that the “InGaAlP semiconductor” referred to herein is a semiconductor represented by a composition formula InₓGa_{y}Al_{1-x-y}P (0≦x≦1.0, 0≦y≦1.0, 0≦x+y≦1). Also, the “AlGaAs semiconductor” is a semiconductor represented by a composition formula Al_{z}Ga_{1-z}As (0≦z≦1). Also, the “substrate” means a crystalline sheet. The “wafer” refers to both a substrate and a semiconductor buffer layer formed on the substrate, by crystal growth of the same material as that of the substrate, or only the substrate.

### BRIEF DESCRIPTION OF THE DRAWINGS

FIG. 1 is a sectional view of a semiconductor device according to a first embodiment of the present invention.

FIG. 2 is a sectional view showing the method of manufacturing the semiconductor device according to the first embodiment of the present invention.

FIG. 3 is a sectional view, continued from FIG. 2, also showing the method of manufacturing the semiconductor device according to the first embodiment of the present invention.

FIG. 4 is a sectional view, continued from FIG. 3, also showing the semiconductor device according to the first embodiment of the present invention.

FIG. 5 is a sectional view, continued from FIG. 4, also showing the semiconductor device according to the first embodiment of the present invention.

FIG. 6 is a sectional view, continued from FIG. 5, also showing the semiconductor device according to the first embodiment of the present invention.

FIG. 7 shows a distribution of carrier density in the wafer surface according to the first embodiment of the present invention.

FIG. 8 shows an in-depth distribution of carrier density in the wafer surface according to the first embodiment of the present invention.

FIG. 9 is a sectional view showing a method of manufacturing the semiconductor device according to a second embodiment of the present invention.

FIG. 10 shows a distribution of carrier density in the wafer surface according to the second embodiment of the present invention.

FIG. 11 shows an in-depth distribution of carrier density in the wafer surface according to the second embodiment of the present invention.

FIG. 12 shows the structure of a sample used in the experiments the present invention is based on.

FIG. 13 shows a substrate used in the experiments the present invention is based on.

FIG. 14 shows a relation between an adhering surface carrier density and a device voltage for the device.

### DETAILED DESCRIPTION OF THE INVENTION

Hereinafter, the unique results of the experiments made by the inventor of the present invention, on which the present invention is based, will be illustrated and explained prior to the detailed description of the embodiments of the present invention.

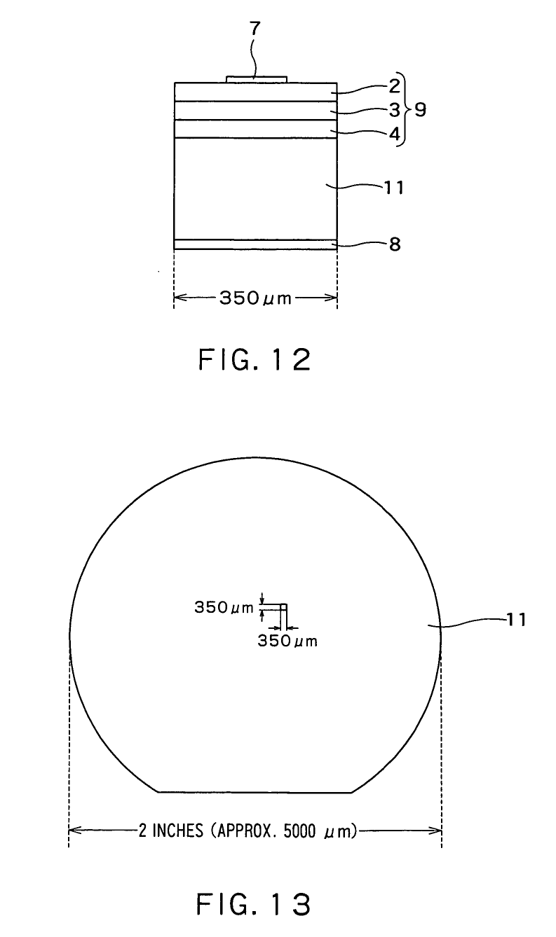

The inventor of the present invention conducted experiments on a transparent substrate-type semiconductor light emitting device formed from a light emitting layer of InGaAlP semiconductor and a transparent GaP substrate, and discovered that there was a close relation between a carrier density distribution at the adhesive interface between the light emitting layer and substrate, and a device voltage of the device (referred to as “device voltage” hereunder). FIG. 12 is a sectional view showing the structure of a sample used in the experiments. As shown, a light emitting layer 9 of a InGaAlP semiconductor is formed on a GaP substrate 11 of p type (first conductive type) having Zn (p-type impurity) doped therein and a thickness of several hundred micrometers. The light emitting layer 9 includes a p-type clad layer (first conductive-type semiconductor layer) 4, active layer 3 and an n-type clad layer 2. On the n-type clad layer 2, there is formed an n-side electrode 7 which is a one-side electrode. A p-side electrode 8, which is another-side electrode, is formed on the bottom of the p-type GaP substrate 11 as in FIG. 12. The semiconductor device shown in FIG. 12 is about 350 μm wide (W), and about 350 μm deep (L). The semiconductor device in FIG. 12 is manufactured by forming the light emitting layer 9 on a p-type GaP substrate 11 having a diameter of 2 inches (about 50000 μm) as shown in FIG. 13 and then cutting the substrate 11 into chips each of 350×350 μm in size.

In the aforementioned transparent substrate-type semiconductor light emitting device, the InGaAlP semiconductor forming the light emitting layer 9 is longer in bandgap wavelength that the GaP forming the substrate 11. Therefore, being permeable to the light from the light emitting layer 9, the GaP substrate 11 contributes to an improved light extraction efficiency. To prevent the light absorption, the GaP substrate 11 has the surface carrier density thereof controlled to 5×10¹⁸ cm⁻³ or less. Thus, the light extraction efficiency can further be improved by controlling the carrier density in this way.

The inventor prepared a number of commercially available p-type GaP substrates 11 shown in FIG. 13 and measured the distribution of carrier density on the surface of the p-type Gap substrates 11. In these experiments, the carrier density was measured by the C-V method in a somewhat wide region, then the density of Zn was measured accurately by the SIMS method in each position on the substrate 11 and the measurements thus obtained were analyzed. The results of analysis revealed that the distribution of carrier density in the surface of the commercially available p-type GaP substrate 11 was nonuniform, varying in a range from 5.0×10¹⁷ cm⁻³ to 5.0×10¹⁸ cm⁻³ from one position to another in the substrate 11.

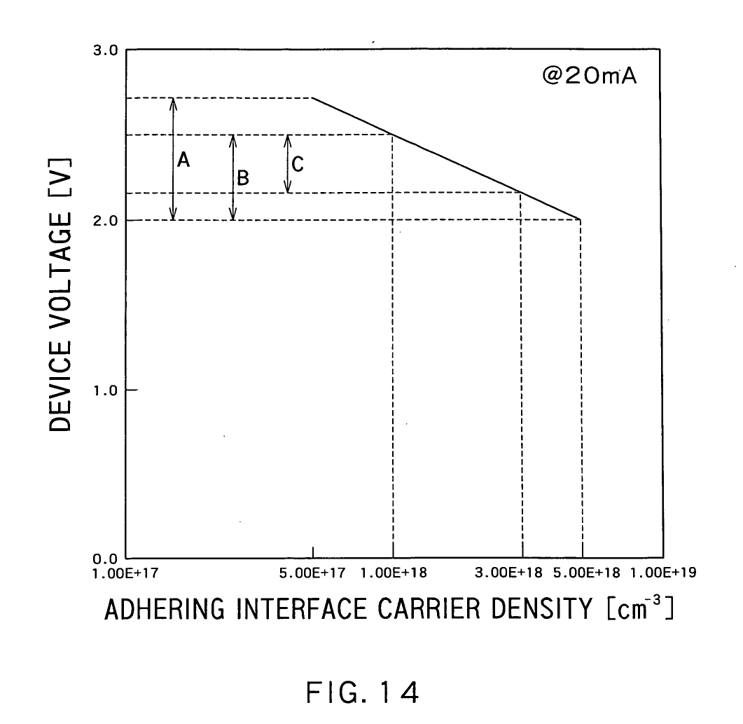

The inventor conducted experiments to examine the relation between the carrier density on the surface of the p-type GaP substrate 11 and the device voltage. The results of the experiments are shown in FIG. 14.

In FIG. 14, the “adhesive interface carrier density” refers to a carrier density on the surface in the p-type GaP substrate 11. The “adhesive interface carrier density [cm⁻³]” is indicated along the horizontal axis while the “device voltage [V]” is indicated along the vertical axis. On the assumption that the horizontal axis is a logarithmic scale and vertical axis is a linear scale, the adhesive interface carrier density and device voltage are in a linear relation with each other as will be seen from FIG. 14. Also, it will be known from FIG. 14 that when the carrier density on the surface of the p-type GaP substrate 11 is nonuniform within the above range from 5.0×10¹⁷ cm⁻³ to 5.0×10¹⁸ cm⁻³, the device voltage is also caused to vary within a range A of about 2.0 to 2.7 V. The results of the inventor experiments proved that in case the adhesive interface carrier density was lower and thus the device voltage was higher than specified, the semiconductor device would fail as being defective. Namely, semiconductor devices cannot be obtained with a high yield from portions of the substrate 11 shown in FIG. 13, whose adhesive interface carrier density is low.

That is, the results of the experiments the inventor's made revealed that the semiconductor device 100 as in FIG. 12 could not be obtained with a high yield from a portion of the p-type GaP substrate 11 (see FIG. 13), where the adhesive interface carrier density is low.

The present invention will be described in detail below concerning the embodiments thereof on the basis of the data shown in FIG. 14 with reference to the accompanying drawings. Two embodiments of the present invention will be illustrated and explained below.

### First Embodiment

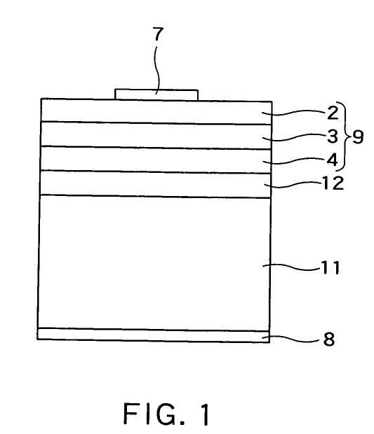

FIG. 1 is a sectional view of a semiconductor device according to the first embodiment of the present invention. This semiconductor device is an LED (light emitting diode) which emits light when a current is injected into it. As shown, the LED includes a p-type (first conductive-type) GaP substrate 11 of several hundred micrometers, and a GaP buffer layer 12 formed from GaP having Zn doped therein and whose thickness is 0.2 μm, and a light emitting layer 9 of InGaAlP semiconductor formed in this order on the GaP substrate 11. The light emitting layer 9 includes a 0.5 μm-thick p-type clad layer (first conductive-type semiconductor) 4 of In_{0.49}(Ca_{0.3}Al_{0.7})_{0.51}P having Zn doped therein and whose carrier density (p-type carrier density) is 1.0×E16 to 1.0×E19 cm⁻³, a 0.5 μm-thick active layer 3 of non-doped In_{0.49}(Ga_{0.75}Al_{0.25})_{0.51}P, and a 0.5 μm-thick n-type clad layer 2 of In_{0.49}(Ga_{0.3}Al_{0.7})_{0.51}P having Si doped therein and whose carrier density (n-type carrier density) is 1.0×E17 to 1.0×E19 cm⁻³. Of these layers, the active layer 3 is smaller in Al composition and bandgap energy than the n-type clad layer 2 and p-type clad layer 4. That is, the light emitting layer 9 has a structure in which the active layer 3 lower in bandgap energy is sandwiched between the clad layers 2 and 4 higher in bandgap energy. On the n-type clad layer 2 included in the light emitting layer 9, there is formed an n-side electrode 7 which is one-side electrode. A p-side electrode 8 as an other-side electrode is formed on the bottom of the p-type GaP substrate 11 as shown in FIG. 1. The semiconductor device shown in FIG. 1 is about 350 μm wide (W) and about 350 μm deep (L). It should be noted that although the substrate 11 has a thickness of several hundred micrometers and the light emitting layer 9 and GaP buffer layer 12 are 1.7 μm thick, they are shown in changed scales, respectively, for easier understanding of the structure of the semiconductor device.

In the semiconductor device shown in FIG. 1, when a current is injected between the n- and p-side electrodes 7 and 8, the active layer 3 will emit light mainly vertically, or upward and downward (namely, toward the n- and p-side electrodes 7 and 8). It is assumed here for the convenience of illustration and explanation that the direction toward the n-side electrode 7 is “upward” and that toward the p-side electrode 8 is “downward”. Of the light emitted from the active layer 3, a part emitted upward is extracted at the top of the semiconductor device. In the semiconductor device in FIG. 1, the GaP substrate 11 is permeable to the light from the active layer 3. Thus, in the semiconductor device shown in FIG. 1, a part of the light emitted downward from the active layer 3 will be reflected upward at the p-side electrode 8, and also extracted at the top of the semiconductor device. In short, the permeability of the p-type GaP substrate 11 to the light from the active layer 3 increases the optical power of the semiconductor device 1 shown in FIG. 1.

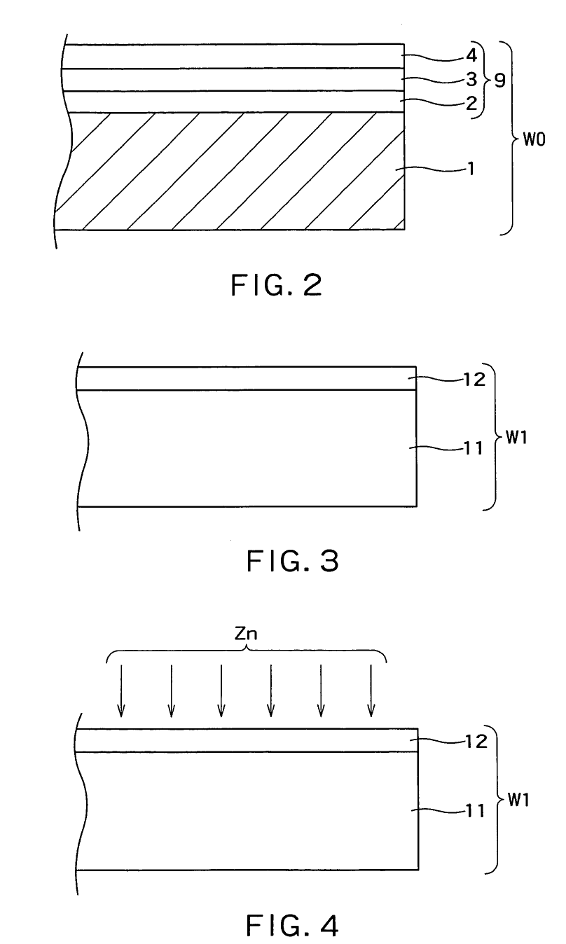

Next, the method of manufacturing the semiconductor device in FIG. 1 will be described with reference to FIGS. 2 to 6.

(1) First, the light emitting layer 9 is formed on an n-type GaAs substrate 1 of 2 inches (about 5 cm=50000 μm) in diameter (see FIG. 13) by the MOCVD (metal organic chemical vapor deposition) method to provide a semiconductor device W0 as shown in FIG. 2. More specifically, the n-type GaAs substrate 1 is placed into an MOCVD apparatus in which trimethyl gallium (TMG), trimethyl aluminum (TMA) and trimethyl indium (TMIn) and phosphine (PH₃) are used as reactive gases, SiH₄ is used as an n-type impurity material (for addition of an n-type impurity) and hydrogen (H₂) is used as a carrier gas. An n-type clad layer 2 of In_{0.49}(Ga_{0.3}Al_{0.7})_{0.51}P is formed at a temperature of about 500 to 900° C. in the MOCVD apparatus. Thereafter, the reactive gas TMA is supplied in a reduced volume while TMG is supplied in an increased volume and the supply of SiH₄ is cut off, to thereby form an active layer 3 of non-doped In_{0.49}(Ga_{0.75}Al_{0.25})_{0.51}P. Further, in the MOCVD apparatus, reactive gases similar to those for forming the n-type clad layer 2 are used and dimethyl zinc (DMZ) is used as a p-type impurity material to form a p-type clad layer 4 of In_{0.49}(Ga_{0.3}Al_{0.7})_{00.51}P. It should be noted here that the GaAs substrate 1 is impermeable to the light from the active layer 3.

(2) The MOCVD method is employed to have a non-doped GaP buffer layer 12 grow to a thickness of 0.2 μm on the p-type GaP substrate 11 of 2 inches in diameter as shown in FIG. 3. More particularly, the p-type GaP substrate 11 is placed into the MOCVD apparatus, TMG, PH₃ and hydrogen (H₂) as a carrier gas are introduced into the apparatus, and the apparatus is kept at a temperature of about 500 to 900° C. without any p-type impurity material to induce an epitaxial growth of the GaP buffer layer 12.

(3) Then, Zn ion is doped by the ion implantation method into the GaP buffer layer 12 on the GaP substrate 11 to form an adhesion wafer W1 (layers 11 and 12) as shown in FIG. 4. For the ion doping, an impurity (Zn+ion) is injected into the GaP buffer layer 12 by a field acceleration. The injecting conditions are an acceleration energy of about 500 cV, irradiation time of 10 minutes and a dosage ranging from 3.0×E18 to 5.0×E18 atom/cm². Thereafter, the GaP buffer layer 12 is annealed. More specifically, an AlN film is formed as an anneal cap film by sputtering over the GaP buffer layer 12, and the Zn ion is activated by annealing at a high temperature. The annealing is conducted in an atmosphere of N₂ at a flow rate of 1000 ccm at 900° C. for 30 min. The acceleration energy, irradiation time, dosage, annealing conditions, etc. are set for the maximum carrier density in the GaP buffer layer to be 3.0×E18 cm⁻³. After the annealing, the AIN film as the anneal cap film is removed by a wet etching using a buffered hydrofluoric acid (HF:NH₄F=1:6).

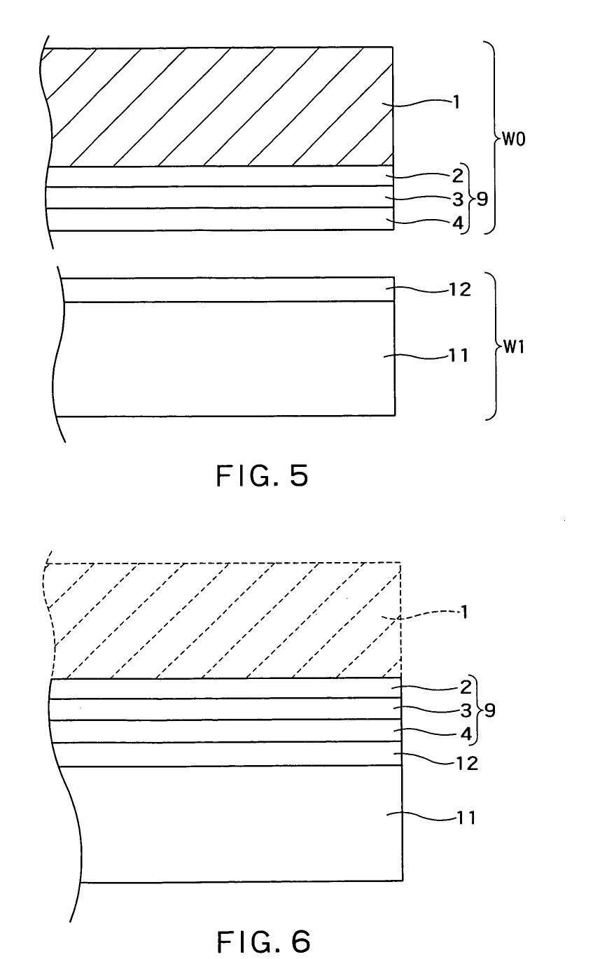

(4) Next, the semiconductor device W0 shown in FIG. 2 is inverted for combination with the wafer W1 in FIG. 4 as shown in FIG. 5. Then, the p-type clad layer 4 in the light emitting layer 9 of the semiconductor device W0 in FIG. 2 is adhered at the surface thereof to the surface of the GaP buffer layer 12 in the wafer W1 (layers 11 and 12) in FIG. 4. This adhesion is conducted by heating the semiconductor devices W0 and W1 at a temperature of 700° C. with the p-type clad layer 4 and GaP buffer layer 12 being kept in contact with each other while pressing the semiconductor devices W0 and W1 toward each other under a pressure of about 0.1 to 10 kg/cm².

(5) Next, the GaAs substrate 1 impermeable to the light from the active layer 3 is etched away using a mixture of H₂O₂ and H₂SO₄ as shown in FIG. 6. Thereafter, a p-side electrode 8 is formed by forming an Au-Ti alloy or Au-Zn-Ni alloy on the lower surface of the p-type GaP substrate 11 by vacuum deposition or the like. Also, an n-side electrode 7 is formed by depositing a layer of Au-Ge-Ni alloy or the like on the entire surface of the n-type clad layer 2 in the light emitting layer 9. After that, the substrate 11 of 2 inches (about 50000 μm) in diameter is cut into a plurality of semiconductor device chips of 350×350 μm in size. Thus, an LED shown in FIG. 1 is formed.

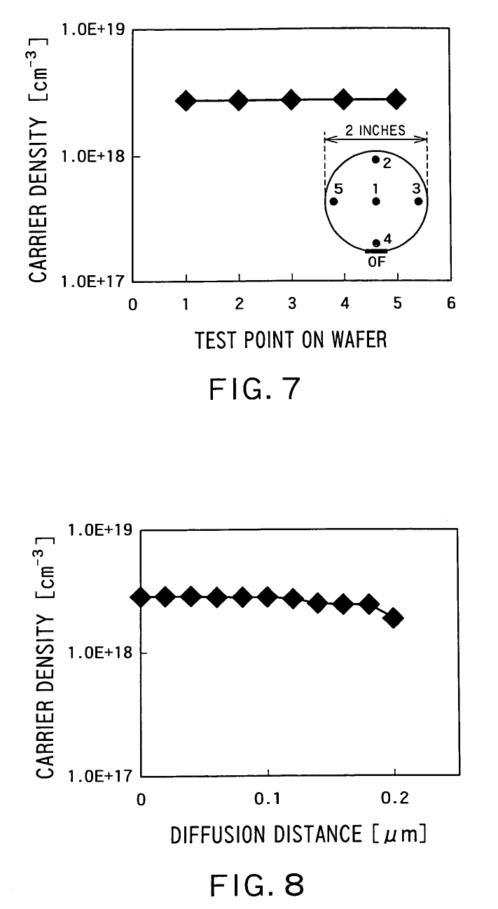

In the semiconductor device in FIG. 1, manufactured by the aforementioned method, since the Zn ion is injected into the GaP buffer layer 12 by the ion implantation method, doping can be made for a stable carrier density by setting the inside carrier density of the GaP buffer layer 12 to a range from 1.0×E18 to 3.0×E18 cm⁻³. Thus, the semiconductor device can be manufactured with an improved yield. This will further be explained below with reference to FIGS. 7, 8 and 14.

FIG. 7 shows the distribution of adhesive interface carrier density of the GaP buffer layer 12 in the wafer (layers 11 and 12) in FIG. 1. The carrier density is calculated by determining a mean carrier density in the GaP buffer layer 12 by the C-V method, examining the distribution of Zn density in detail by the SIMS analysis and then analyzing the results of the examination of mean carrier density and Zn density distribution. FIG. 7 shows the distribution of carrier density at five points in the plane of a two-inch wafer. As will be known from FIG. 7, the wafer (layers 11 and 12) shown in FIG. 1 has an extremely high uniformity in surface distribution of carrier density in the GaP buffer layer 12.

FIG. 8 shows the in-depth distribution of carrier density in the GaP buffer layer 12 at the center of the wafer (layers 11 and 12) in FIG. 1. This carrier frequency is also calculated by determining a mean carrier density in the GaP buffer layer 12 by the C-V method, examining the distribution of Zn density in detail by the SIMS analysis and then analyzing the results of the examination of mean carrier density and Zn density distribution. It should be noted here that the diffusion distance along the horizontal axis means the depth from the surface. As will be known from FIG. 8, the in-depth carrier density of 0.2 μm shown in FIG. 1 is stable within a range from 1.0×E18 to 3.0×E18 cm⁻³ to a depth of 0.2 μm, that is, along the full depth of the GaP buffer layer 12.

In the wafers in FIG. 1, when the GaP buffer layer 12 has a thickness of 0.2 μm and maximum carrier density is 3.0×E18 cm⁻³, the nonuniformity of the inside carrier density of the GaP buffer layer 12 will fall within a range C of 1.0×E18 to 3.0×E18 cm⁻³. Thus, the surface carrier density of the GaP buffer layer 12 is also within the range of 1.0×E18 to 3.0×E18 cm⁻³. Therefore, as seen from FIG. 14, the device voltage of each of the semiconductor device can be stabilized in a range C of about 2.15 to 2.5 V. As a result, it is possible to operate each semiconductor device with a specific voltage, not with a higher voltage than specified, and thus manufacture the semiconductor devices with an improved yield.

On the other hand, when a p-type impurity material is used to form the p-type GaP buffer field 12 on a transparent GaP substrate 11 by the MOCVD method and the GaP buffer layer 12 is adhered to the p-type clad layer 4, the nonuniformity of the distribution of carrier density in the GaP buffer layer 12 will increase so that the semiconductor devices cannot be manufactured with an improved yield.

Also, since the commercially available p-type GaP substrate 11 is usable directly to manufacture the semiconductor device shown in FIG. 1, no special process including a control of the carrier density in the p-type GaP substrate 11 or the like is required, which will restrain the semiconductor device manufacturing cost.

In the semiconductor device having been described above with reference to FIG. 1, the ion injection is done for the GaP buffer layer 12 to have a maximum carrier density of 3.0×E18 cm⁻³. By changing the acceleration energy, irradiation time, dosage, annealing conditions, etc., however, the ion injection for the GaP buffer layer 12 can produce a maximum carrier density of 5.0×E18 cm⁻³. In this case, the inside carrier density and surface carrier density of the GaP buffer layer 12 can be controlled to a range from 1.0×E18 cm⁻³ to 5.0×E18 cm⁻³. Thus, the device voltage can be stabilized to a range B of about 2.0 to 2.5 V as shown in FIG. 14, and it is possible to operate each semiconductor device with a specific voltage, not with a higher voltage than specified, and thus manufacture the semiconductor devices with an improved yield.

On the other hand, when the maximum carrier density exceeds 5.0×E18 cm⁻³, the p-type impurity (Zn) will absorb the light, resulting in a reduced light extraction efficiency. On this account, the maximum carrier density is set to be under 5.0×E18 cm⁻³.

In the semiconductor device shown in FIG. 1, the p-type GaP buffer layer 12 has a thickness of 0.2 μm. However, the thickness may be within a range from 0.1 μm to 5.0 μm. On the contrary, when the thickness is less than 0.1 μm, it will be difficult to manufacture semiconductor devices with the improved yield as described above. Also, when the thickness is over 5.0 μm, it will be difficult to inject Zn ion and a longer time will be required until the GaP buffer layer 12 has grown.

Also, with the thickness of the p-type GaP buffer layer 12 set to the range from 0.1 μm to 5.0 μm, the inside carrier density and surface carrier density of the GaP buffer layer 12 can be controlled to a range from 1.0×E18 cm⁻³ to 5.0×E18 cm⁻³. Thus, the device voltage can be stabilized to a range B of about 2.0 to 2.5 V as shown in FIG. 14, and it is possible to operate each semiconductor device with a specific voltage, not with a higher voltage than specified, and thus manufacture the semiconductor devices with an improved yield.

In the semiconductor device having been described above with reference to FIG. 1, the p-type clad layer 4 has a thickness of 0.5 μm, the active layer 3 has a thickness of 0.5 μm and n-type clad layer 2 has a thickness of 0.5 μm. However, these thicknesses may be changed as necessary. For example, these layers may be formed to a thickness of about 0.1 to 2.0 μm. Also, the carrier density in each of these layers 2 to 4 may be appropriately altered.

The semiconductor device in FIG. 1 has a double hetero junction structure in which the active layer 3 is sandwiched between the clad layers 2 and 4 and the active layer 3, clad layers 2 and 4 are formed from materials different in mixed crystal ratio of aluminum (Al), for example, so that carriers can be confined in the active layer 3 more easily and thus the active layer 3 is used as the light emitting layer. However, the semiconductor device may be formed to have a structure in which the p-n junction is formed without interposition of the active layer 3 and light is emitted from the p-n junction. That is, the semiconductor device may be formed to have a structure identical to that shown in FIG. 1 but not including the active layer 3.

Also, the semiconductor device in FIG. 1 has been explained as a light emitting device formed from a combination of the GaP wafer W1 (layers 11 and 12) and InGaAlP semiconductor layer 9 in the semiconductor device W0. However, the GaP wafer W1 (layers 11 and 12) and a semiconductor device W0 having an AlGaAs semiconductor layer may be combined together to form a light emitting device. Also, to manufacture a light emitting device, the GaP wafer W1 may be combined with a semiconductor layer of any other material as necessary. More particularly, since the GaP wafer is permeable to light having a wavelength of about 550 nm or more, it may be combined with a semiconductor layer whose bandgap wavelength is about 550 nm or more.

Also, in the semiconductor device shown in FIG. 1, each of the p- and n-type layers may take the other's place.

### Second Embodiment

In the semiconductor device manufacturing method according to the second embodiment of the present invention, Zn ion is injected into a GaP buffer layer 12 by the solid phase diffusion method in place of the ion implantation method. The structure of the semiconductor device manufactured according to the second embodiment is similar to that of the semiconductor device manufactured according to the first embodiment (as in FIG. 1), and so will not be described in detail. The method of manufacturing the semiconductor device shown in FIG. 1 will be described below with reference to FIGS. 2, 3, 9, 5 and 6.

(1) As in the first embodiment, on a GaAs substrate 1 (see FIG. 7) of 2 inches (about 5 cm) in diameter, there is first formed by the MOCVD method a light emitting layer 9 including an n-type clad layer 2 of about 0.1 to 2 μm in thickness, active layer 3 of about 0.1 to 2 μm in thickness and a p-type clad layer 4 of about 0.1 to 2 μm in thickness, as will be seen in FIG. 2.

(2) Also as in the first embodiment, a non-doped GaP buffer layer 12 is formed on a p-type GaP substrate 11 of 2 inches in diameter to a thickness of 0.2 μm by the MOCVD method, as shown in FIG. 3.

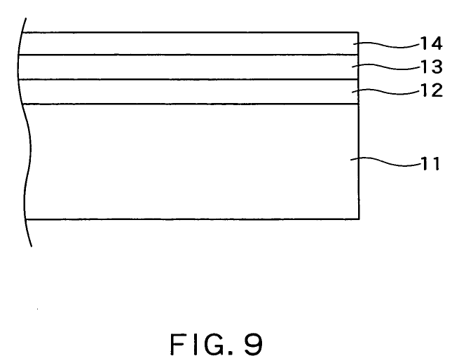

(3) Then, a diffusion source film 13 formed from an ZnO-SiO₂ mixture is formed on the GaP buffer layer 12 in FIG. 3, and an anneal cap film 14 of AIN is formed by sputtering on the diffusion source film 13, as shown in FIG. 9. Thereafter, the Z ion of the diffusion source film 13 is diffused by annealing at a high temperature into the GaP buffer layer 12. The high-temperature annealing is conducted in an atmosphere of N₂ at a flow rate of 1000 ccm at 700° C. for 60 min. These annealing conditions are set to have the maximum carrier density in the GaP buffer layer be about 3.0×E18 cm^{-3.}

(4) Next, the anneal cap film 14 and diffusion source film 13 in FIG. 9 are removed using a buffered hydrofluoric acid. After that, the p-type clad layer 4 in the light emitting layer 9 in FIG. 2 is adhered at the surface thereof to the surface of the GaP buffer layer 12 included in the wafer (layers 11 and 12) in FIG. 4, as shown in FIG. 5.

(5) Then, the GaAs substrate 1 impermeable to light from the active layer 3 is etched away using a mixture of H₂O₂ and SO₄ as shown in FIG. 6. Thereafter, a p-side electrode 8 and n-side electrode 7 are formed, and the substrate 11 of 2 inches (about 50000 μm) in diameter is cut into a plurality of semiconductor device chips of 350×350 μm. Thus, an LED shown in FIG. 1 is formed.

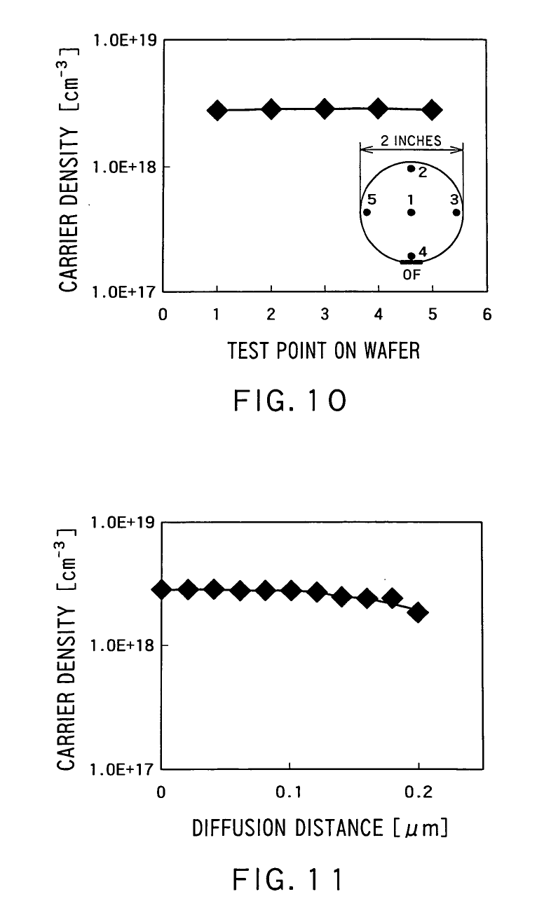

In the semiconductor device manufactured by the method according to the second embodiment of the present invention, Zn is doped in the GaP buffer layer 12 by the solid phase diffusion method as shown in FIG. 9. Thus, the carrier density distributions in and on the surface of the GaP buffer layer 12 can be limited in nonuniformity to within a range of 1.0×E18 to 3.0×E18 cm⁻³ as shown in FIGS. 10 and 11. As a result, it is possible to operate each semiconductor device with a specific voltage, not with a higher voltage than specified, and thus manufacture the semiconductor devices with an improved yield, as in the aforementioned first embodiment.

In the semiconductor device manufactured according to the second embodiment, having been described in the foregoing, doping is conducted for the maximum carrier density in the GaP buffer layer 12 to be 3.0×E18 cm⁻³. By changing the annealing conditions, however, the ion injection can also done for the GaP buffer layer 12 to have a maximum carrier density of 5.0×E18 cm⁻³. In this case, the inside carrier density and surface carrier density of the GaP buffer layer 12 can be controlled to within a range from 1.0×E18 cm⁻³ to 5.0×E18 cm^{-3.}

Although in the semiconductor device manufactured according to the second embodiment, the p-type GaP buffer layer 12 has a thickness of 0.2 μm, it may be formed to have a thickness falling within a range from 0.1 μm to 5.0 μm.

Also, by forming the p-type GaP buffer layer 12 to have a thickness within a range from 0.1 μm to 5.0 μm, the inside carrier density and surface carrier density of the GaP buffer layer 12 can be controlled to within a range from 1.0×E18 cm⁻³ to 5.0×E18 cm⁻³. Thus, it is possible to stabilize the device voltage within a range B of about 2.0 to 2.5 V as shown in FIG. 14, and operate each semiconductor device with a specific voltage, not with a higher voltage than specified, and thus manufacture the semiconductor devices with an improved yield.

The semiconductor device manufactured according to the second embodiment uses the InGaAlP semiconductor as the light emitting layer 9, but it may use the AlGaAs semiconductor. Also, the semiconductor device manufactured according to the second embodiment has a double hetero junction structure in which the active layer 3 is sandwiched between the clad layers 2 and 4 and the active layer 3, clad layers 2 and 4 are formed from materials different in mixed crystal ratio of aluminum (Al), for example, so that carriers can be confined in the active layer 3 more easily and thus the active layer 3 is used as the light emitting layer. However, the semiconductor device may be formed to have a structure in which the p-n junction is formed without interposition of the active layer 3 and light is emitted from the p-n junction.

Also, the semiconductor layers forming the semiconductor light emitting devices manufactured according to the aforementioned embodiments are formed from specific semiconductor materials having specific thickness and carrier density. However, the present invention is not limited to such embodiments.

As having been described in the foregoing, since by the semiconductor device manufacturing method including a step of adhering the first conductive-type GaP wafer to the first conductive type semiconductor later, the GaP wafer is manufactured by forming the GaP buffer layer on the GaP substrate by the MOCVD method without using any first conductive-type impurity material, and then doping a first conductive-type impurity into the GaP buffer layer by the ion implantation method or solid phase diffusion method, so it is possible to manufacture the semiconductor devices with an improved yield while preventing the wafer surface carrier density from being nonuniform in distribution. Also, since by the GaP wafer producing method, the GaP buffer layer is formed on the GaP substrate by the MOCVD method without using any first conductive-type impurity material and then a first conductive-type impurity is doped into the GaP buffer layer by the ion implantation method or solid phase diffusion method, the carrier density can be prevented from being nonuniform in distribution on the wafer surface.

1. A method for manufacturing a semiconductor device comprising:
forming a GaP buffer layer on a first conductive-type GaP substrate serving as a first substrate by an MOCVD method without using a first conductive-type impurity material;
doping a first conductive-type impurity into the GaP buffer layer by an ion implantation method;
forming a light emitting layer on a GaAs substrate serving as a second substrate;
adhering the light emitting layer on the GaAs substrate and the GaP buffer layer on the GaP substrate to each other; and
removing the GaAs substrate, which is opaque to light from the light emitting layer.

2. The method for manufacturing a semiconductor device according to claim 1, wherein:
the light emitting layer is formed on the GaAs substrate as a double hetero structure including a second conductive-type semiconductor layer, an active layer emitting light passing through the GaP substrate and a first conductive-type semiconductor layer; and
the first conductive-type semiconductor layer and the GaP buffer layer are adhered to each other.

3. The method for manufacturing a semiconductor device according to claim 1, wherein:
the light emitting layer is formed on the GaAs substrate as a p-n junction structure in which a second conductive-type semiconductor layer and a first conductive-type semiconductor layer are adhered to each other; and
the first conductive-type semiconductor layer and the GaP buffer layer are adhered to each other.

4. The method for manufacturing a semiconductor device according to claim 1, wherein an InGaAlP or AlGaAs base semiconductor layer is formed as the light emitting layer.

5. The method for manufacturing a semiconductor device according to claim 1, wherein a semiconductor layer having a bandgap wavelength of about 550 nm or more is formed as the light emitting layer.

6. The method for manufacturing a semiconductor device according to claim 1, wherein the first conductive-type is p or n type and the second conductive-type is n or p type.

7. The method for manufacturing a semiconductor device according to claim 1, wherein the first conductive-type impurity to be doped into the GaP buffer layer is Zn.

8. The method for manufacturing a semiconductor device according to claim 1, wherein the doping of the first conductive-type impurity into the GaP buffer layer is performed so that the GaP buffer layer has a density in a range from 1.0×E18 cm⁻³ to 3.0×E18 cm⁻³ or a range from 1.0×E18 cm⁻³ to 5.0×E18 cm⁻³.

9. A method for manufacturing a semiconductor device comprising:
forming a GaP buffer layer on a first conductive-type GaP substrate serving as a first substrate by an MOCVD method without using a first conductive-type impurity material;
doping a first conductive-type impurity into the GaP buffer layer by a solid phase diffusion method;
forming a light emitting layer on a GaAs substrate serving as a second substrate;
adhering the light emitting layer on the GaAs substrate and the GaP buffer layer on the GaP substrate to each other; and
removing the GaAs substrate, which is opaque to light from the light emitting layer.

10. The method for manufacturing a semiconductor device according to claim 9, wherein:
the light emitting layer is formed on the GaAs substrate as a double hetero structure including a second conductive-type semiconductor layer, an active layer emitting light passing through the GaP substrate and a first conductive-type semiconductor layer; and
the first conductive-type semiconductor layer and the GaP buffer layer are adhered to each other.

11. The method for manufacturing a semiconductor device according to claim 9, wherein:
the light emitting layer is formed on the GaAs substrate as a p-n junction structure in which a second conductive-type semiconductor layer and a first conductive-type semiconductor layer are adhered to each other; and
the first conductive-type semiconductor layer and the GaP buffer layer are adhered to each other.

12. The method for manufacturing a semiconductor device according to claim 9, wherein an InGaAlP or AlGaAs base semiconductor layer is formed as the light emitting layer.

13. The method for manufacturing a semiconductor device according to claim 9, wherein a semiconductor layer having a bandgap wavelength of about 550 nm or more is formed as the light emitting layer.

14. The method for manufacturing a semiconductor device according to claim 9, wherein the first conductive-type is p or n type and the second conductive-type is n or p type.

15. The method for manufacturing a semiconductor device according to claim 9, wherein the first conductive-type impurity to be doped into the GaP buffer layer is Zn.

16. The method for manufacturing a semiconductor device according to claim 9, wherein the doping of the first conductive-type impurity into the GaP buffer layer is performed so that the GaP buffer layer has a density in a range from 1.0×E18 cm⁻³ to 3.0×E18 cm⁻³ or a range from 1.0×E18 cm⁻³ to 5.0×E18 cm^{-3.}

17. The method for manufacturing a semiconductor device according to claim 9, wherein the doping of the first conductive-type impurity by the solid phase diffusion method into the GaP buffer layer is achieved by:
forming a diffusion source film including ZnO on the GaP buffer layer;
forming an anneal cap film including AIN on the diffusion source film; and
diffusing Zn ion by the high-temperature annealing into the GaP buffer layer.

18. A method for manufacturing a wafer comprising:
forming a GaP buffer layer on a first conductive-type GaP substrate as a first substrate by the MOCVD method without using a first conductive-type impurity material; and
doping a first conductive-type impurity into the GaP buffer layer by the ion implantation method.

19. The method for manufacturing a semiconductor device according to claim 18, wherein the doping of the first conductive-type impurity into the GaP buffer layer is performed so that the GaP buffer layer has a density in a range from 1.0×E18 cm⁻³ to 3.0×E18 cm⁻³ or a range from 1.0×E18 cm⁻³ to 5.0×E18 cm^{-3.}

20. A method for manufacturing a wafer comprising:
forming a GaP buffer layer on a first conductive-type GaP substrate as a first substrate by the MOCVD method without using a first conductive-type impurity material; and
doping a first conductive-type impurity into the GaP buffer layer by the solid phase diffusion method.

21. The method for manufacturing a semiconductor device according to claim 20, wherein the doping of the first conductive-type impurity by the solid phase diffusion method into the GaP buffer layer is achieved by:
forming a diffusion source film including ZnO on the GaP buffer layer;
forming an anneal cap film including AIN on the diffusion source film; and
diffusing Zn ion by the high-temperature annealing into the GaP buffer layer.

22. The method for manufacturing a semiconductor device according to claim 20, wherein the doping of the first conductive-type impurity into the GaP buffer layer is performed so that the GaP buffer layer has a density in a range from 1.0×E18 cm⁻³ to 3.0×E18 cm⁻³ or a range from 1.0×E18 cm⁻³ to 5.0×E18 cm⁻³.
